(19) United States
(12) Patent Application Publication
(10) Pub. No.: US 2023/0128173 A1
(43) Pub. Date: Apr. 27, 2023

(54) MODULARIZED DIGITAL TWIN CREATION FOR PHYSICAL INFRASTRUCTURE OF COMPUTING ENVIRONMENT

(71) Applicant: Dell Products L.P., Round Rock, TX (US)

(72) Inventors: Danqing Sha, Shanghai (CN); Zhen Jia, Shanghai (CN); Said Tabet, Austin, TX (US); Jiacheng Ni, Shanghai (CN)

(21) Appl. No.: 17/506,888

(22) Filed: Oct. 21, 2021

(51) Int. Cl. G06F 30/20

(52) U.S. Cl. CPC G06F 30/20

(57) ABSTRACT

Techniques are disclosed for modularly creating a virtual representation of physical infrastructure of a computing environment. For example, a method comprises generating a virtual representation of physical components of a computing environment. The virtual representation is generated by enabling selection of templates from a pre-stored template database wherein the templates respectively represent the physical components, and by integrating the selected templates with one another to collectively represent the physical components. The method then manages the physical components via the virtual representation.

### FIELD

The field relates generally to computing environments, and more particularly to managing physical infrastructure in such computing environments.

### BACKGROUND

Recently, techniques have been proposed to attempt to represent infrastructure in a computing environment so as to more efficiently manage the infrastructure including attributes and operations associated with the infrastructure. One proposed way to represent the infrastructure is through the creation of a digital twin architecture. A digital twin typically refers to a virtual representation (e.g., virtual copy) of a physical (e.g., actual or real) product, process, and/or system. By way of example, a digital twin can be used to understand, predict, and/or optimize performance of a physical product, process, and/or system in order to achieve improved operations in the computing environment in which the product, process, and/or system is implemented. However, the creation of digital twins for various types of infrastructure in a given computing environment can be a significant challenge.

### SUMMARY

Embodiments provide techniques for modularly creating a virtual representation (e.g., digital twin) of physical infrastructure of a computing environment.

According to one illustrative embodiment, a method comprises generating a virtual representation of physical components of a computing environment. The virtual representation is generated by enabling selection of templates from a pre-stored template database wherein the templates respectively represent the physical components, and by integrating the selected templates with one another to collectively represent the physical components. The method then manages the physical components via the virtual representation.

In further illustrative embodiments, each template of at least a subset of the templates may comprise one or more of: (i) a model component which is configured to represent one or more parameters of the corresponding physical component, and which comprises one or more interfaces to enable communication between templates integrated within the virtual representation; (ii) a simulation component which is configured to provide evaluation of the virtual representation prior to the virtual representation being used to manage the physical components; (iii) a real time data component which is data associated with one or more real time operations of the corresponding physical component; (iv) a historical data component which is data associated with one or more previous operations of the corresponding physical component; and (v) a data analytics component which is configured to analyze data associated with the corresponding physical component.

In yet other illustrative embodiments, the method may manage the physical components via the virtual representation by evaluating the virtual representation to determine whether or not the virtual representation is functioning as intended, and modifying or rebuilding the virtual representation based on results of the evaluation.

Further illustrative embodiments are provided in the form of a non-transitory computer-readable storage medium having embodied therein executable program code that when executed by a processor causes the processor to perform the above steps. Still further illustrative embodiments comprise an apparatus with a processor and a memory configured to perform the above steps.

These and other features and advantages of embodiments described herein will become more apparent from the accompanying drawings and the following detailed description.

### BRIEF DESCRIPTION OF THE DRAWINGS

FIG. 1 illustrates a modularized digital twin creation environment according to an illustrative embodiment.

FIG. 2 illustrates modularized digital twin creation functionality according to an illustrative embodiment.

FIG. 3 illustrates a user flow for a modularized digital twin creation methodology according to an illustrative embodiment.

FIG. 4 illustrates exemplary module templates for modularized digital twin creation according to an illustrative embodiment.

FIG. 5 illustrates a modularized digital twin creation methodology according to an illustrative embodiment.

FIG. 6 illustrates a processing platform for an information processing system used to implement modularized digital twin creation functionality according to an illustrative embodiment.

### DETAILED DESCRIPTION

Illustrative embodiments will now be described herein in detail with reference to the accompanying drawings. Although the drawings and accompanying descriptions illustrate some embodiments, it is to be appreciated that alternative embodiments are not to be construed as limited by the embodiments illustrated herein. Furthermore, as used herein, the term “includes” and its variants are to be read as open-ended terms that mean “includes, but is not limited to.” The term “based on” is to be read as “based at least in part on.” The term “an embodiment” and “the embodiment” are to be read as “at least one example embodiment.” The terms “first,” “second,” and the like may refer to different or the same objects. Other definitions, either explicit or implicit, may be included below.

As mentioned above in the background section, digital twins are virtual representations of assets and processes that are used to understand, predict, and optimize performance in order to achieve improved performance outcomes. A digital twin can act as a bridge between the physical and digital worlds and can be created by collecting real-time data about the physical product, process, and/or system. The data is then used to create a digital duplicate of the physical item, allowing it to be understood, analyzed, manipulated, and/or optimized. However, there are significant challenges that arise with existing approaches to creating such digital twins. For example, it is realized that technical problems exist in terms of challenges around modeling, complexity and integration of digital twins.

More particularly, it is realized herein that model fidelity can have significant impact on the lifecycle utility of the digital twin as well as the lifecycle support cost of the solution. High precision, multi-physics modeling, with high-fidelity response simulation are important and remain a challenge for creating a satisfactory digital twin. Furthermore, it is realized herein that most three-dimensional (3D) models available to create digital twins contain a large amount of information that is not always necessary for the operation of the digital twin, especially for complex or physically large-sized physical systems that are being modeled. Also, the larger the model, the more computational resources are needed. Thus, it is realized herein that lightweight models are needed to enable digital twin architectures to visualize and simulate complex systems and systems of systems, including their physical behaviors, in real-time and with acceptable computational costs.

In addition, it is realized that the process to develop a satisfactory digital twin with high fidelity using existing digital twin creation techniques is complex and typically costly. Existing digital twin creation techniques are mostly customized based on specific use cases or scenarios, and usually require building the digital twin from scratch, including traversing the entire process of modeling, simulation, collecting real time data, synchronization, and validation of the digital twin, each time a digital twin is created. Still further, such existing techniques fail to integrate critical intelligence during digital twin creation.

Illustrative embodiments provide technical solutions that overcome the above and other challenges with existing digital twin creation techniques by modularizing the creation process. As will be explained in further detail, modularized creation of digital twins according to illustrative embodiments addresses technical problems that existing techniques do not such as, but not limited to, how to better allocate resources, how to optimize the creation efficiency based on use cases, how to adaptively and intelligently select digital twin components with different fidelity to create a desired digital twin, and how to connect the digital twin components automatically to synchronize with the physical system, to name a few. Illustrative embodiments provide technical solutions that address these and other technical problems by, inter alia, managing multi-source, multi-format data and correlating it to other data where there is no obvious link, as well as understanding the underlying enterprise (e.g., business) for which the digital twin is created and shaping outcomes by adjusting inputs in a feedback loop.

More particularly, illustrative embodiments provide a modularized platform and methodology to create a digital twin of information technology (IT) infrastructure of a given computing environment. By way of example only, illustrative embodiments enable creation of a digital twin for hardware and corresponding software, a digital twin for cloud infrastructure, a digital twin for edge infrastructure, a digital twin for a multi-access edge computing (MEC) system, a digital twin for a data center, a digital twin for one or more computing devices that are part of the computing environment, etc. Further, digital twins of each physical component can be integrated together (combined) to form a digital twin of a complex physical system that includes the physical components. It is to be appreciated that embodiments are not limited to the particular infrastructure or computing environment examples illustratively described herein.

As will be illustratively explained below in the context of the accompanying figures, illustrative embodiments provide an adaptative digital twin template matching functionality. That is, standard (pre-stored in a template database or library) templates for digital twin elements are available which can be adaptively selected to create an integrated digital twin quickly based on the real-time system situations or use cases. Each of the templates or digital twin elements can act as a digital copy of real IT infrastructure components, and visualize a 3D model with indications of real time data/status including network, central processing unit (CPU) usage, storage usage, run time, latency, temperature, energy consumption, warning/alerts, etc. The integrated digital twin can then act as a digital copy of the real IT infrastructure, and also simulate different workloads/architectures based on user inputs and can be used for optimization design of IT infrastructure based on various workloads, user trajectories, latencies, costs, energy consumptions, etc.

Advantageously, illustrative embodiments reduce cost and increase efficiency by enabling assembly and integration of a digital twin with templates rather than building the digital twin from scratch. Illustrative embodiments provide better visibility during assembly of a digital twin since a user can continually view the integration of the entire system or devices, and the status of interconnected systems in a more interactive and real-time manner during digital twin integration and development. Further, illustrative embodiments enable what-if analysis so that a user can easily interact with the digital twin models and templates to simulate unique conditions and perform predictions to obtain optimized solutions or setup. Still further, illustrative embodiments provide intelligence by enabling automatic optimization with a tradeoff analysis between different parameters based on use cases or scenarios while selecting different fidelities of templates.

The modularized digital twin creation techniques according to illustrative embodiments enable an enterprise such as, but not limited to, an original equipment manufacturer (OEM) or provider to improve performance throughout the product lifecycle, increase reliability and availability, reduce risk, improve production, lower maintenance costs, and achieve faster time to value. More particularly, modularized digital twin creation for IT infrastructure helps improve system design and optimization, eliminating the need for physical prototypes, reducing development time, and improving the quality of the finalized solutions. Illustrative embodiments can also provide modularized digital twin creation as a service.

A modularized digital twin creation methodology, as will be further explained herein, makes digital twin development much simpler, more effective, and more intuitive with a better user experience. In some embodiments, a modularized digital twin creation methodology can be deployed in augmented reality/virtual reality (AR/VR) headsets, glasses, or goggles which can provide a more intuitive virtual experience/interaction with better user experience. Additionally or alternatively, a modularized digital twin creation methodology can be deployed in a personal computer, a smart device or other web-based tool.

The above and other features and advantages of modularized digital twin creation will now be further explained in the context of the accompanying figures.

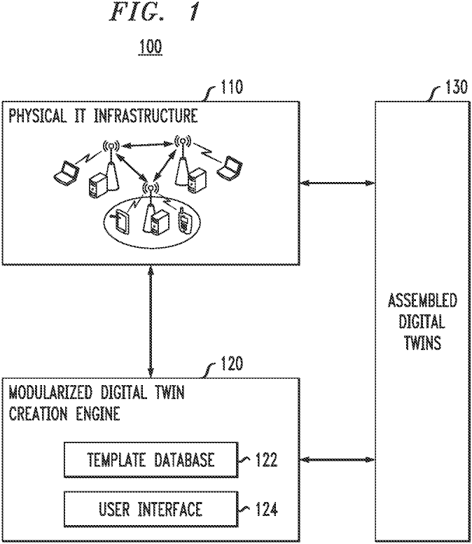

FIG. 1 illustrates a modularized digital twin creation environment 100 according to an illustrative embodiment. As shown, modularized digital twin creation environment 100 comprises physical IT infrastructure 110 of a given computing environment operatively coupled to a modularized digital twin creation engine 120 and one or more assembled digital twins 130. Modularized digital twin creation engine 120 generates one or more assembled digital twins 130 (e.g., full asset twins) for physical IT infrastructure 110 by integrating/combining different digital twin templates. The digital twin templates are developed and pre-stored in a template database 122 for selection via a user interface 124, as will be further described in detail herein. Once assembled digital twins 130 are created, real-time data exchange between physical IT infrastructure 110 and assembled digital twins 130 occurs so as to understand, predict, and/or optimize performance of the components of physical IT infrastructure 110. By way of example only, components of physical IT infrastructure 110 may comprise hardware and corresponding software, cloud infrastructure, edge infrastructure, a multi-access edge computing (MEC) system, one or more data centers, one or more computing devices such as internet-connected or Internet of Things (IoT) devices, etc.

It is to be understood that IoT broadly refers to a vast system of internet-connected devices that are able to receive and/or collect and transfer data over a wireless network without human intervention or with minimal human intervention. The nature and purpose of such IoT devices are essentially unlimited, e.g., smart phones, laptops, vehicles, sensors, actuators, etc., in a wide variety of operational environments that form one or more IoT platforms. Typically, the wireless network to which the IoT devices connect enables the IoT devices to connect with an edge computing network (e.g., one or more edge servers). Edge computing, considered the evolution of cloud computing, migrates the deployment of application programs (applications) from a centralized data center downward to distributed edge nodes, thereby achieving shorter distances from data generated by consumers (e.g., IoT devices) and the applications. Examples of applications include, but are not limited to, applications implementing artificial intelligence (AI) models such as, but not limited to, machine learning (ML) applications, deep learning (DL) applications, and data mining (DM) applications. Many IoT devices and edge servers are also typically configured to utilize 3GPP 5G cellular technology to send and receive data.

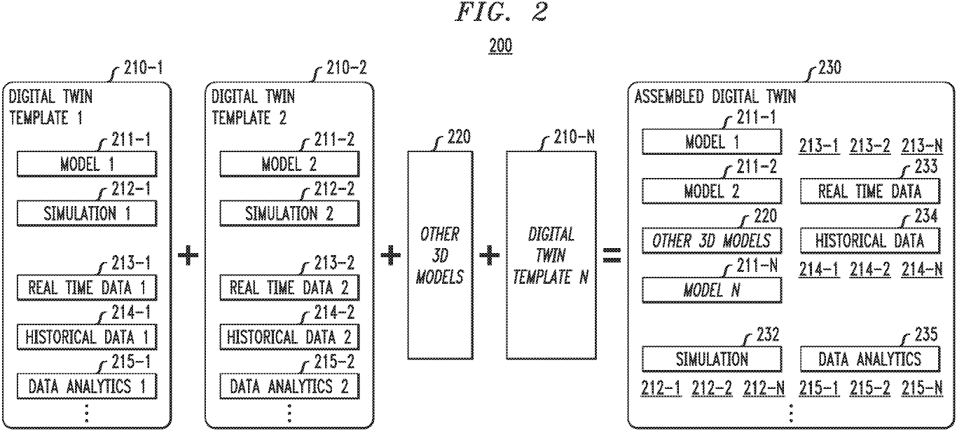

FIG. 2 illustrates modularized digital twin creation functionality 200 according to an illustrative embodiment. As explained above in the context of FIG. 1, modularized digital twin creation engine 120 generates one or more assembled digital twins 130 for physical IT infrastructure 110 by integrating/combining different digital twin templates to form one or more assembled digital twins. More particularly, FIG. 2 illustrates an example of the integration/combination of multiple digital twin templates 210-1, 210-2, ..., 210-N (which may be referred to herein individually as digital twin template 210 and collectively as digital twin templates 210) that are combined with one or more other 3D models 220 to create an assembled digital twin 230.

As shown, each digital twin template 210 comprises a model component (211-1, 211-2, ..., 211-N which may be referred to herein individually as model component 211 and collectively as model components 211), a simulation component (212-1, 212-2, ..., 212-N which may be referred to herein individually as simulation component 212 and collectively as simulation components 212), a real time data component (213-1, 213-2, ..., 213-N which may be referred to herein individually as real time data component 213 and collectively as real time data components 213), a historical data component (214-1, 214-2, ..., 214-N which may be referred to herein individually as historical data component 214 and collectively as historical data components 214), and a data analytics component (215-1, 215-2, ..., 215-N which may be referred to herein individually as data analytics component 215 and collectively as data analytics components 215). In some embodiments, a given digital twin template 210 may comprise a subset of components 211 through 215.

Recall that modularized digital twin creation engine 120 of FIG. 1 intelligently selects templates, as well as other models, and integrates/combines them to generate an assembled digital twin. Thus, as shown in FIG. 2, assembled digital twin 230 comprises model component 211-1 from digital twin template 210-1, model component 211-2 from digital twin template 210-2, ..., model component 210-N from digital twin template 210-N, one or more other 3D models 220, a combined simulation component 232 that comprises simulation components 212-1, 212-2, ..., 212-N, a combined real time data component 233 that comprises real time data components 213-1, 213-2, ..., 213-N, a combined historical time data component 234 that comprises historical data components 214-1, 214-2, ..., 214-N, and a combined data analytics component 235 that comprises data analytics components 215-1, 215-2, ..., 215-N.

It is to be appreciated that other assembled digital twins 230 can have different combinations of integrated components than the one illustrated in FIG. 2, depending on the IT management need. Further, it is to be understood that each of digital twin templates 210 or components thereof can also themselves serve as respective virtual representations (digital twins) of the corresponding real IT infrastructure components and visualize 3D models, real time data/status including network, CPU/storage usage, run time, latency, temperature, energy consumption, warning/alerts, etc.

In some embodiments, model components 211 can be 3D models, or discrete event based models, agent based model, etc. Simulation components 212 can be software configured to predict performance of the physical components of the corresponding digital twin templates 210 with which the simulation components 212 are associated. By way of example only, simulation software can be used to help IT administrators understand whether, and under what conditions, a physical IT infrastructure component could fail and/or what performance loads it can withstand. Real time data components 213 can be data received by the assembled digital twin 230 during online/real time operations once operatively connected to the physical IT component(s) with which they are associated. Historical data components 214 can be data received during previous online/real time operations or otherwise obtained by the assembled digital twin 230 for the physical IT component(s) with which they are associated. Data analytics components 215 can be AI/ML/DL based data analytics algorithms which can provide different functions based on different use cases.

For physical IT infrastructure, there can be a wide variety of categories of digital twin templates 210. By way of example only, categories can include: digital twin templates for some generic hardware in the IT infrastructure (such as, but not limited to, a server, storage, a network switch, etc.), digital twin templates for IoT sensors (such as, but not limited to, a temperature sensor, a presence sensor, a smoke detector, a camera, etc.), digital twin templates for network systems, and digital twin templates for any other hardware or devices within the IT infrastructure.

In some embodiments, other 3D models 220 can be included together with digital twin templates 210 during assembly and integration when necessary to make the assembled digital twin 230 complete and the same as the physical counterpart. Non-limiting examples of such other 3D models 220 are 3D models for electronic equipment racks, 3D models for sensors, 3D models for heating, ventilation, and air conditioning (HVAC) systems, building information modeling (BIM) models including building structure and layouts, etc.

As explained herein, assembled digital twin 230 can be a digital representation of a complex system of physical components. For example, assembled digital twin 230 can combine one or more digital twin templates for a set of hardware, one or more digital twin templates for edge computing infrastructure, one or more digital twin templates for cloud computing infrastructure, one or more digital twin templates for a MEC system, one or more digital twin templates for a data center, etc.

In addition, once created, digital twin templates for generic hardware, edge infrastructure, cloud infrastructure, MEC systems, data centers, IoT devices, etc. can be stored in a template database (e.g., 122 of FIG. 1) within or otherwise accessible by modularized digital twin creation engine 120 and thus can be selected via a user interface (124 of FIG. 1) as templates for use cases once needed. Then, once operatively coupled to the actual physical component which they virtually (or logically) represent, a selected digital twin template 210 receives input data and provides output data based on its specific use case configuration.

Example inputs of a digital twin template 210 for hardware can include, but are not limited to, real time system data, environment data, hardware configurations or parameters (e.g., CPU/virtual machine parameters). Example outputs of a digital twin template 210 for hardware can include, but are not limited to, data indicative of transmission latency, computational latency, CPU utilization, energy consumption, failed tasks, etc.

Example inputs of a digital twin template 210 for a MEC system can include, but are not limited to, real time system data, environmental data, user movement trajectory, user device transmit power, router queuing latency, network transmission bandwidth and speed, edge CPU/virtual machine parameters, mobile offloading task data such as sizes of offloading tasks, the total CPU cycle number required to accomplish an offloading task, and latency requirements, etc. Example outputs of a digital twin template 210 for a MEC system can include, but are not limited to, analysis results (computed from at least a portion of the inputs) for transmission latency, computational latency, communication latency, offloading latency, CPU utilization, energy consumption, failed task rate, optimal design recommendations of a cloud-edge system, etc.

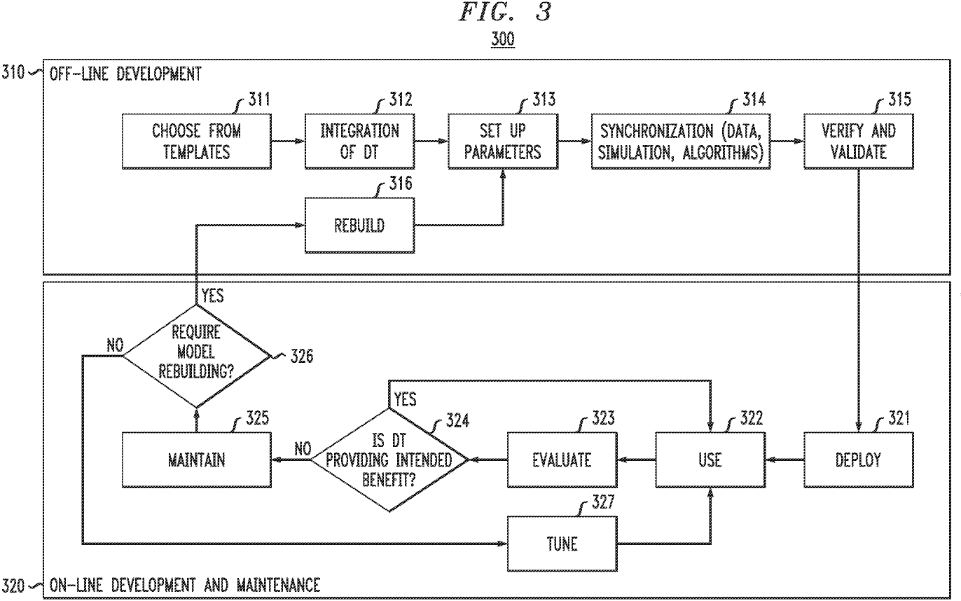

FIG. 3 illustrates a digital twin creation methodology 300 according to an illustrative embodiment. It is to be understood that steps of digital twin creation methodology 300 are executed by or otherwise caused to be executed by modularized digital twin creation engine 120 of FIG. 1. Recall that modularized digital twin creation engine 120 comprises a user interface 124 to enable a user (e.g., IT administrator) to make selections (e.g., select templates from template database 122) and/or otherwise perform actions as needed/desired during the digital twin creation lifecycle associated with digital twin creation methodology 300. As shown in FIG. 3, digital twin creation methodology 300 comprises an off-line development lifecycle part 310 comprising steps 311 through 316 and an on-line (e.g., real time) deployment and maintenance lifecycle part 320 comprising steps 321 through 327.

Accordingly, in step 311, one or more digital twin templates (e.g., 210 of FIG. 2) are chosen e.g., digital twin templates are manually and/or automatically selected as needed/desired, as well as any 3D models (220 of FIG. 2).

In step 312, selected digital twin templates and models are integrated together based on specific use case criteria. By way of one example only, the user via the user interface may decide which templates/models to include in the assembled digital twin or DT (e.g., 230 of FIG. 3) based on physical positions and/or locations of the actual IT infrastructure.

In step 313, parameters are set in each digital twin template to simulate and customize the digital twins for the physical IT infrastructure. Likewise, parameters are set in the assembled digital twin to ensure alignment with the physical IT infrastructure.

In step 314, synchronization occurs of the newly assembled digital twin with the physical IT infrastructure to obtain real time data (e.g., 233 of FIG. 2) and historical data (e.g., 234 of FIG. 2) as needed based on specific synchronization criteria for the intended use case. Also, simulation and data analytics integration is performed between the selected digital twin templates of the newly assembled digital twin.

In step 315, the newly assembled digital twin is verified and validated with its physical counterpart based on specific verification/validation criteria for the intended use case.

Digital twin creation methodology 300 then transitions from off-line development lifecycle part 310 to on-line deployment and maintenance lifecycle part 320.

In step 321, the newly assembled digital twin is deployed (e.g., operatively coupled to the corresponding physical infrastructure).

In step 322, the deployed newly assembled digital twin is run/executed (used).

In step 323, the executed newly assembled digital twin is evaluated against specific operational criteria for the intended use case.

Step 324 determines whether or not the assembled digital twin is operating based on the intended criteria and thus providing the intended benefit for the specific use case.

If yes in step 324 (YES branch), the assembled digital twin continues to execute (return to step 322 and the methodology iterates).

If no in step 324 (NO branch), maintenance is performed (maintain) in step 325 on the assembled digital twin to attempt to correct/adjust any operational issues.

Step 326 determines, based on the extent of the corrections/adjustments in step 325, whether or not the assembled digital twin and/or any template/model therein needs to be rebuilt.

If yes in step 326 (YES branch), digital twin creation methodology 300 returns to off-line development lifecycle part 310 where, in step 316, a rebuild is performed to create a re-assembled digital twin (at which point, the methodology returns to step 313 and iterates).

If no in step 326 (NO branch), meaning that a complete rebuild is not needed, step 327 tunes the assembled digital asset based on the corrections/adjustments made in step 325 and the assembled digital twin continues to execute (return to step 322 and the methodology iterates).

Advantageously, instead of building a digital twin from scratch each time, modularized digital twin creation methodology 300 uses modularized templates to create an assembled digital twin quickly and more efficiently. Further, modularized digital twin creation methodology 300 enables a user to simulate and test assumptions about designs of systems before implementation, and conduct optimization and evaluation about different scenarios by assembling different templates quickly. Still further, modularized digital twin creation methodology 300 supports AR/VR based visualization and remote control.

Recall as shown in FIG. 2 that two or more digital twin templates 210 are integrated with one another to form the assembled digital twin 230. It is realized herein that the integration between different digital twin templates 210 is useful because each template has its own models and/or modules. According to illustrative embodiments, such challenges are addressed from four perspectives: model/module integration; simulation; data; and data analytics.

Model/module integration. In order to support seamless integration of different templates for digital twin creation, illustrative embodiments address two design factors:
(i) Each template has standardized application programming interfaces (APIs). The inputs, outputs and communication protocols are standardized across different templates. In this way, when different models/modules of different templates are integrated, the integration will not trigger any issue and different models/modules can be fully connected together.
(ii) After each model/module of different templates is connected together, it is helpful to define a data path or data flow testing plan. The data path or flow testing is used as a way to check the communication between different models/modules from the first input to the integrated system all the way to the last output from the integrated system. With this data path tested thoroughly, the engine can conclude the integration is fully complete without any communication, protocol and other intersection issues.

Simulation. Simulation also follows a similar process as model/module integration. For different models/modules, the engine ensures that the APIs are fully standardized and can be seamlessly integrated. Once this is achieved, then the simulation can treat these integrated models/modules as one complete model/module to provide inputs and run the simulations to obtain outputs. Simulation software as used in accordance with illustrative embodiments has many benefits, such as it can test services in a repeatable and controllable environment, tune system bottlenecks before deploying on real clouds, and simulate the required infrastructure to evaluate different sets of workloads as well as resource performance.

Data. Data here also follows a similar process as model/module integration. The interfaces between different model/modules are standardized so the data path or flow through all models/modules is smooth without any obstacles. One challenge addressed by illustrative embodiments is that the different models/modules may have different kinds of data formats, different kinds of data definitions and so on. Thus, while the data path or flow can be smooth, processing these disparate data efficiently is a challenge. Illustrative embodiments address this challenge by identification of data and codification of relationships between disparate data. To manage complex integration of digital twin templates requires making sense of multisource, multiformat data and correlating it to other data where there is no obvious link.

Data analytics. Because of different kinds of data formats and data definitions during the models/modules integration, data analytics can also be challenging. Illustrative embodiments leverage tensor data processing to handle the data sources from multiple models/modules. A tensor is a container which can house data in N dimensions, along with its linear operations. With tensor, various kinds of data are handled in a single container for processing. Also, tensor data processing maintains the original semantic relationships between different kinds of data without losing its own connections, formats or definitions.

To increase the modularity of the digital twin creation engine according to illustrative embodiments, the following features and functionalities can be implemented in the digital twin templates.

Models can be include, but are not limited to:
(i) Reduced order models for hardware or other devices can be used as a visualization and interaction interface (e.g., server, storage, switch, sensors, etc.).
(ii) 3D models for data center layout or even BIM models for building.
(iii) Discrete event based models or agent based models can also be used to create the assembled digital twin.
(iv) Models are developed as part of digital twin templates.

Simulation can include but is not limited to:
(i) IT architecture simulation software such as CloudSim or EdgeCloudSim can be used to simulate cloud-edge architecture and simulate performance of a product.
(ii) For other physical simulations, such as finite element analysis (FEA) and computational fluid dynamics (CFD) analysis, corresponding simulation tools can be used.
(iii) The simulation software is encapsulated into the digital twin templates.

Analytics and prediction can include, but is not limited to:
(i) AI/ML/DL algorithms to determine optimal configuration.
(ii) Different AI/ML/DL algorithms can be leveraged based on different scenarios or use cases.
(iii) AI/MI/DL algorithms are encapsulated into the digital twin templates.

Visualization can include, but is not limited to:

PC based, web based or AR based visualizations including Smart pad or AR headsets, glasses, or goggles by way of example.

As mentioned above, CloudSim and EdgeCloudSim are tools that are leveraged for simulation of cloud/edge computing infrastructures and services. EdgeCloudSim is a simulation environment specific to edge computing scenarios. EdgeCloudSim is based on CloudSim but adds some additional functionalities such as network modelling specific to WLAN and WAN, device mobility model, and realistic and tunable load generator.

Furthermore, it is to be appreciated that there are multiple levels of fidelity for digital twin templates. For some complicated systems, the user does not have to choose high-fidelity models or templates which can increase system computation resource requirements.

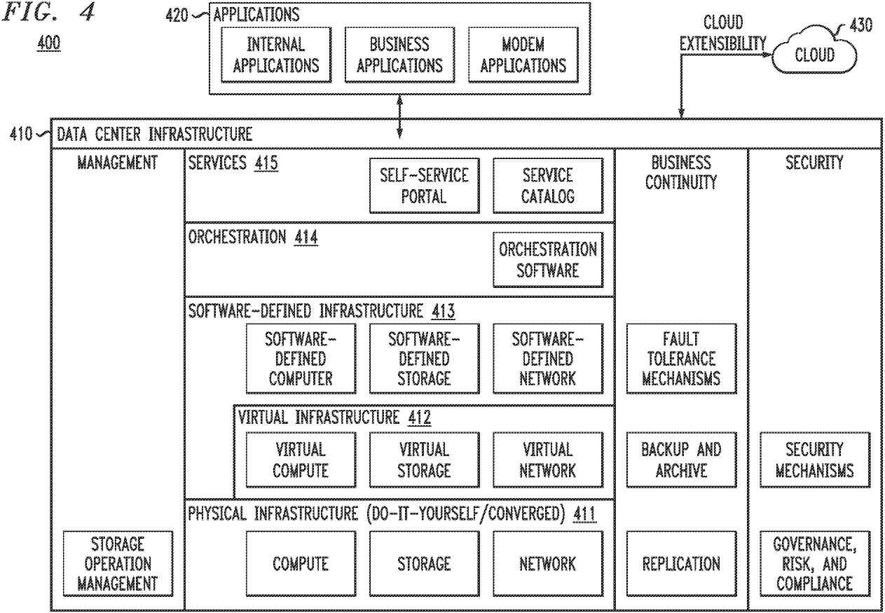

For example, consider a data center as an example. FIG. 4 illustrates exemplary modular templates in the context of a data center scenario 400 with a data center infrastructure 410, applications 420 and a cloud platform 430. As shown, for modern data center infrastructure, from the bottom physical infrastructure layer 411, to virtual infrastructure 412, to software-defined infrastructure 413, up to an orchestration layer 414 and a services layer 415, illustrative embodiments provide for creating different kinds of templates based on different customer requirements and needs. The detailed templates can include, for example, a computer template, a storage template, a fabric template, a virtualization template, an orchestration template and so on. The engine then enables selection of different levels of digital twin templates intelligently based on user inputs/requirements, performance requirements, computation cost, etc. with automatic optimization and tradeoff between different parameters based on use cases or scenarios. The various digital twin templates can be categorized for selection based on fidelity.

Low fidelity. As the lowest level, low fidelity templates can provide output to input response for process loops and discrete devices, where uncontrolled input-output (IO) usually only have static values, and are appropriate for the lowest implementation and computation cost.

Medium fidelity. This level defines modeling between low and high fidelity. Medium fidelity templates can be a good compromise of performance and computation cost, as this template can run automatically and respond to automation system actions and changes.

High fidelity. The value of high fidelity digital twin templates is more realistic performance and dynamic transitions over a full operating range. The template can run automatically and respond to automation system actions and changes in a very similar manner to the physical counterpart. In general, high fidelity template development requires more data up front and may have a higher lifecycle cost and computation cost.

In some embodiments, an AI based optimization selects the different fidelity levels of digital twins intelligently.

Visualization in accordance with a modularized digital twin creation engine can be implemented in AR or VR headsets, glasses, or goggles, in which case, a user can remotely visualize 3D visualizations of the entire digital twin creation process, navigate in the assembled digital twin model to view the structure and data, and use gestures/controllers to retrieve real-time data or digital information. Users can also control model tuning, synchronization and validation using such visualizations. An advantage of AR/VR integration with digital twins is the ability to visualize all possible processes and data in a 3D environment, where the user can interact with the template, and manipulate the information by interaction with the virtual environment in an intuitive and straightforward manner. Using an AR or VR headset, the user can also view the entire process as well as all data in real time from multiple perspectives.

FIG. 5 illustrates a methodology 500 for modularized digital twin creation according to an illustrative embodiment. Step 502 generates a virtual representation of physical components of a computing environment, wherein the virtual representation is generated by enabling selection of templates from a pre-stored template database wherein the templates respectively represent the physical components, and by integrating the selected templates with one another to collectively represent the physical components. Step 504 manages the physical components via the virtual representation. Illustrative details and examples of these steps are explained in detail herein.

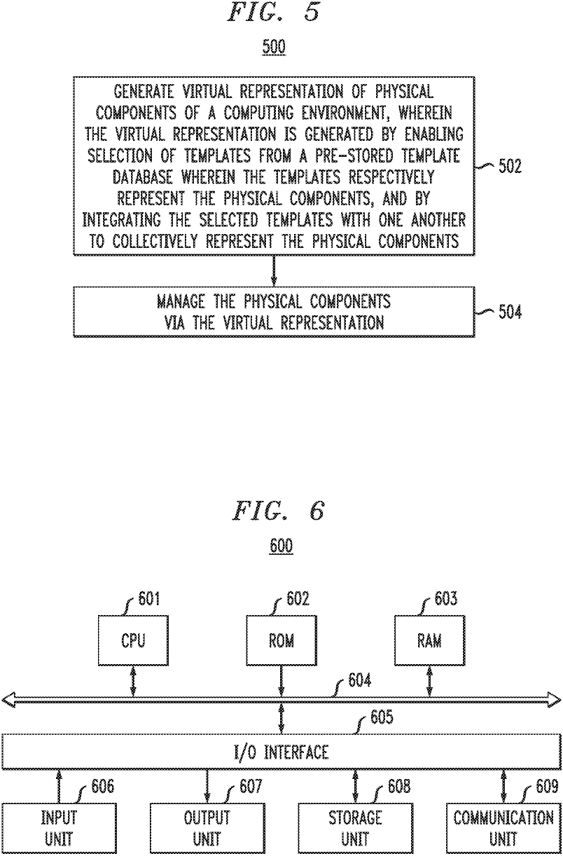

FIG. 6 illustrates a block diagram of an example processing device or, more generally, an information processing system 600 that can be used to implement illustrative embodiments. For example, one or more components in FIGS. 1-5 can comprise a processing configuration such as that shown in FIG. 6 to perform steps/operations described herein. Note that while the components of system 600 are shown in FIG. 6 as being singular components operatively coupled in a local manner, it is to be appreciated that in alternative embodiments each component shown (CPU, ROM, RAM, and so on) can be implemented in a distributed computing infrastructure where some or all components are remotely distributed from one another and executed on separate processing devices. In further alternative embodiments, system 600 can include multiple processing devices, each of which comprise the components shown in FIG. 6.

As shown, the system 600 includes a central processing unit (CPU) 601 which performs various appropriate acts and processing, based on a computer program instruction stored in a read-only memory (ROM) 602 or a computer program instruction loaded from a storage unit 608 to a random access memory (RAM) 603. The RAM 603 stores therein various programs and data required for operations of the system 600. The CPU 601, the ROM 602 and the RAM 603 are connected via a bus 604 with one another. An input/output (I/O) interface 605 is also connected to the bus 604.

The following components in the system 600 are connected to the I/O interface 605, comprising: an input unit 606 such as a keyboard, a mouse and the like; an output unit 607 including various kinds of displays and a loudspeaker, etc.; a storage unit 608 including a magnetic disk, an optical disk, and etc.; a communication unit 609 including a network card, a modem, and a wireless communication transceiver, etc. The communication unit 609 allows the system 600 to exchange information/data with other devices through a computer network such as the Internet and/or various kinds of telecommunications networks.

Various processes and processing described above may be executed by the CPU 601. For example, in some embodiments, methodologies described herein may be implemented as a computer software program that is tangibly included in a machine readable medium, e.g., the storage unit 608. In some embodiments, part or all of the computer programs may be loaded and/or mounted onto the system 600 via ROM 602 and/or communication unit 609. When the computer program is loaded to the RAM 603 and executed by the CPU 601, one or more steps of the methodologies as described above may be executed.

Illustrative embodiments may be a method, a device, a system, and/or a computer program product. The computer program product may include a computer readable storage medium having computer readable program instructions thereon for causing a processor to carry out aspects of illustrative embodiments.

The computer readable storage medium may be a tangible device that can retain and store instructions for use by an instruction execution device. The computer readable storage medium may be, for example, but is not limited to, an electronic storage device, a magnetic storage device, an optical storage device, an electromagnetic storage device, a semiconductor storage device, or any suitable combination of the foregoing. A non-exhaustive list of more specific examples of the computer readable storage medium includes the following: a portable computer diskette, a hard disk, a random access memory (RAM), a read-only memory (ROM), an erasable programmable read-only memory (EPROM or Flash memory), a static random access memory (SRAM), a portable compact disc read-only memory (CD-ROM), a digital versatile disk (DVD), a memory stick, a floppy disk, a mechanically encoded device such as punch-cards or raised structures in a groove having instructions recorded thereon, and any suitable combination of the foregoing. A computer readable storage medium, as used herein, is not to be construed as being transitory signals per se, such as radio waves or other freely propagating electromagnetic waves, electromagnetic waves propagating through a waveguide or other transmission media (e.g., light pulses passing through a fiber-optic cable), or electrical signals sent through a wire.

Computer readable program instructions described herein can be downloaded to respective computing/processing devices from a computer readable storage medium or to an external computer or external storage device via a network, for example, the Internet, a local area network, a wide area network and/or a wireless network. The network may comprise copper transmission cables, optical transmission fibers, wireless transmission, routers, firewalls, switches, gateway computers and/or edge servers. A network adapter card or network interface in each computing/processing device receives computer readable program instructions from the network and forwards the computer readable program instructions for storage in a computer readable storage medium within the respective computing/processing device.

Computer readable program instructions for carrying out operations of illustrative embodiments may be assembler instructions, instruction-set-architecture (ISA) instructions, machine instructions, machine dependent instructions, microcode, firmware instructions, state-setting data, or either source code or object code written in any combination of one or more programming languages, including an object oriented programming language such as Smalltalk, C++ or the like, and conventional procedural programming languages, such as the “C” programming language or similar programming languages. The computer readable program instructions may execute entirely on the user’s computer, partly on the user’s computer, as a stand-alone software package, partly on the user’s computer and partly on a remote computer or entirely on the remote computer or server. In the latter scenario, the remote computer may be connected to the user’s computer through any type of network, including a local area network (LAN) or a wide area network (WAN), or the connection may be made to an external computer (for example, through the Internet using an Internet Service Provider). In some embodiments, electronic circuitry including, for example, programmable logic circuitry, field-programmable gate arrays (FPGA), or programmable logic arrays (PLA) may execute the computer readable program instructions by utilizing state information of the computer readable program instructions to personalize the electronic circuitry, in order to perform aspects of the present disclosure.

Various technical aspects are described herein with reference to flowchart illustrations and/or block diagrams of methods, device (systems), and computer program products according to illustrative embodiments. It will be understood that each block of the flowchart illustrations and/or block diagrams, and combinations of blocks in the flowchart illustrations and/or block diagrams, can be implemented by computer readable program instructions.

These computer readable program instructions may be provided to a processor unit of a general purpose computer, special purpose computer, or other programmable data processing device to produce a machine, such that the instructions, when executed via the processing unit of the computer or other programmable data processing device, create means for implementing the functions/acts specified in the flowchart and/or block diagram block or blocks. These computer readable program instructions may also be stored in a computer readable storage medium that can direct a computer, a programmable data processing device, and/or other devices to function in a particular manner, such that the computer readable storage medium having instructions stored therein includes an article of manufacture including instructions which implement aspects of the function/act specified in the flowchart and/or block diagram block or blocks.

The computer readable program instructions may also be loaded onto a computer, other programmable data processing device, or other devices to cause a series of operational steps to be performed on the computer, other programmable devices or other devices to produce a computer implemented process, such that the instructions which are executed on the computer, other programmable devices, or other devices implement the functions/acts specified in the flowchart and/or block diagram block or blocks.

The flowchart and block diagrams illustrate architecture, functionality, and operation of possible implementations of systems, methods and computer program products according to various embodiments. In this regard, each block in the flowchart or block diagrams may represent a module, snippet, or portion of code, which includes one or more executable instructions for implementing the specified logical function(s). In some alternative implementations, the functions noted in the block may occur out of the order noted in the figures. For example, two blocks in succession may, in fact, be executed substantially concurrently, or the blocks may sometimes be executed in the reversed order, depending upon the functionality involved. It will also be noted that each block of the block diagrams and/or flowchart illustration, and combinations of blocks in the block diagrams and/or flowchart illustration, can be implemented by special purpose hardware-based systems that perform the specified functions or acts, or combinations of special purpose hardware and computer instructions.

The descriptions of the various embodiments have been presented for purposes of illustration, but are not intended to be exhaustive or limited to the embodiments disclosed. Many modifications and variations will be apparent to those of ordinary skill in the art without departing from the scope and spirit of the described embodiments. The terminology used herein was chosen to best explain the principles of the embodiments, the practical application or technical improvement over technologies found in the marketplace, or to enable others of ordinary skill in the art to understand the embodiments disclosed herein.

What is claimed is:

1. A method, comprising:
generating a virtual representation of physical components of a computing environment, wherein the virtual representation is generated by enabling selection of templates from a pre-stored template database wherein the templates respectively represent the physical components, and by integrating the selected templates with one another to collectively represent the physical components; and
managing the physical components via the virtual representation;
wherein the generating and managing steps are performed by at least one processor and at least one memory storing executable computer program instructions.

2. The method of claim 1, wherein each template of at least a subset of the templates comprises a model component which is configured to represent one or more parameters of the corresponding physical component, and which comprises one or more interfaces to enable communication between templates integrated within the virtual representation.

3. The method of claim 1, wherein each template of at least a subset of the templates comprises a simulation component which is configured to provide evaluation of the virtual representation prior to the virtual representation being used to manage the physical components.

4. The method of claim 1, wherein each template of at least a subset of the templates comprises a real time data component which is data associated with one or more real time operations of the corresponding physical component.

5. The method of claim 1, wherein each template of at least a subset of the templates comprises a historical data component which is data associated with one or more previous operations of the corresponding physical component.

6. The method of claim 1, wherein each template of at least a subset of the templates comprises a data analytics component which is configured to analyze data associated with the corresponding physical component.

7. The method of claim 1, wherein each template comprises a selectable fidelity level based on a use case within which the corresponding physical component is intended to operate.

8. The method of claim 1, wherein the step of generating a virtual representation of physical components of a computing environment further comprises integrating one or more three-dimensional models into the virtual representation with the selected templates.

9. The method of claim 1, wherein the step of managing the physical components via the virtual representation further comprises evaluating the virtual representation to determine whether or not the virtual representation is functioning as intended.

10. The method of claim 9, wherein the step of managing the physical components via the virtual representation further comprises modifying the virtual representation based on a result of the evaluation.

11. The method of claim 9, wherein the step of managing the physical components via the virtual representation further comprises rebuilding the virtual representation based on a result of the evaluation.

12. An apparatus, comprising:
at least one processor and at least one memory storing computer program instructions wherein, when the at least one processor executes the computer program instructions, the apparatus is configured to:
generate a virtual representation of physical components of a computing environment, wherein the virtual representation is generated by enabling selection of templates from a pre-stored template database wherein the templates respectively represent the physical components, and by integrating the selected templates with one another to collectively represent the physical components; and
manage the physical components via the virtual representation.

13. The apparatus of claim 12, wherein each template of at least a subset of the templates comprises a model component which is configured to represent one or more parameters of the corresponding physical component, and which comprises one or more interfaces to enable communication between templates integrated within the virtual representation.

14. The apparatus of claim 12, wherein each template of at least a subset of the templates comprises a simulation component which is configured to provide evaluation of the virtual representation prior to the virtual representation being used to manage the physical components.

15. The apparatus of claim 12, wherein each template of at least a subset of the templates comprises a real time data component which is data associated with one or more real time operations of the corresponding physical component.

16. The apparatus of claim 12, wherein each template of at least a subset of the templates comprises a historical data component which is data associated with one or more previous operations of the corresponding physical component.

17. The apparatus of claim 12, wherein each template of at least a subset of the templates comprises a data analytics component which is configured to analyze data associated with the corresponding physical component.

18. The apparatus of claim 12, wherein each template comprises a selectable fidelity level based on a use case within which the corresponding physical component is intended to operate.

19. A computer program product stored on a non-transitory computer-readable medium and comprising machine executable instructions, the machine executable instructions, when executed, causing a processing device to perform steps of:
generating a virtual representation of physical components of a computing environment, wherein the virtual representation is generated by enabling selection of templates from a pre-stored template database wherein the templates respectively represent the physical components, and by integrating the selected templates with one another to collectively represent the physical components; and
managing the physical components via the virtual representation.

20. The computer program product of claim 19, wherein each template of at least a subset of the templates comprises one or more of:
a model component which is configured to represent one or more parameters of the corresponding physical component, and which comprises one or more interfaces to enable communication between templates integrated within the virtual representation;
a simulation component which is configured to provide evaluation of the virtual representation prior to the virtual representation being used to manage the physical components;
a real time data component which is data associated with one or more real time operations of the corresponding physical component;
a historical data component which is data associated with one or more previous operations of the corresponding physical component; and
a data analytics component which is configured to analyze data associated with the corresponding physical component.
